(19) United States
(12) Patent Application Publication
(10) Pub. No.: US 2017/0221681 A1
(43) Pub. Date: Aug. 3, 2017

(54) SUBSTRATE PROCESSING SYSTEM AND SUBSTRATE PROCESSING APPARATUS

(71) Applicant: TOKYO ELECTRON LIMITED, Tokyo (JP)

(72) Inventor: Satoru KAWAKAMI, Miyagi (JP)

(73) Assignee: TOKYO ELECTRON LIMITED, Tokyo (JP)

(21) Appl. No.: 15/328,860

(22) PCT Filed: Jul. 13, 2015
(86) PCT No.: PCT/JP2015/070063

§ 371 Date: Jan. 24, 2017

(30) Foreign Application Priority Data
Jul. 24, 2014 (JP) 2014-151184

(51) Int. Cl. H01J 37/32; H01L 21/67

(52) U.S. Cl. CPC H01J 37/3244; H01J 37/3211; H01L 21/67069; H01L 21/67248; H01J 2237/334

(57) ABSTRACT

A substrate processing system is provided with a transfer module that transports a substrate to be processed, and a plurality of processing units which are mounted and arranged vertically along a side surface of the transfer module, and each of which processes the substrate to be processed. Each of the processing units includes a chamber, a shower head, and a stage. The chamber includes an upper unit that includes a part of a sidewall forming a space in the chamber and that is fitted with the shower head, and a lower unit including the remaining portion of the side wall in the chamber and fitted with the stage. The upper unit and the lower unit are separable in a direction different from the direction in which the plurality of processing units are arranged.

### CROSS REFERENCE TO RELATED APPLICATIONS

This application is a National Stage Application of, and claims priority to, PCT Application No. PCT/JP2015/070063, filed on Ju. 13, 2015, entitled “SUBSTRATE PROCESSING SYSTEM AND SUBSTRATE PROCESSING APPARATUS,” which claims priority to Japanese Patent Application No. 2014-151184, filed on Jul. 24, 2014. The foregoing patent applications are herein incorporated by reference by entirty for all purposes.

### FIELD OF THE INVENTION

Various aspects and embodiments of the present invention relate to a substrate processing system and a substrate processing apparatus.

### BACKGROUND OF THE INVENTION

In order to improve a throughput of substrate processing, a plurality of target substrates may be simultaneously processed by using a plurality of substrate processing apparatuses. In that case, the substrate processing apparatuses are arranged in a facility such as a clean room or the like and, thus, an area occupied by the substrate processing apparatuses is increased. Therefore, a larger clean room is required and an installation cost is increased. Accordingly, a plurality of substrate processing apparatuses is arranged at multiple levels in a vertical direction in order to increase the number of substrate processing apparatuses per unit area.

The substrate processing apparatus includes components such as a stage for mounting thereon a target substrate, a shower head for supplying a processing gas into a chamber of the substrate processing apparatus, and the like. In order to perform a maintenance operation for those components, it is required to open an upper lid of the chamber, take out components such as the stage, the shower head and the like and clean the inside of the chamber. However, when a plurality of substrate processing apparatuses is arranged at multiple levels in a vertical direction, it is not possible to open the upper lid of the chamber upward due to the presence of another substrate processing apparatus provided thereabove.

Therefore, there is known a technique for separating the upper lid of the chamber from a lower portion of the chamber without being disturbed by another substrate processing apparatus provided thereabove by shifting the upper lid of the chamber in a horizontal direction (see, e.g., Patent Document 1).

Patent Document 1: Japanese Patent Application Publication No. H10-299900

In the technique of Patent Document 1, by shifting the lid of the chamber, it is possible to separate and clean the components such as the shower head attached to the lid and the like. In order to separate the components such as the stage and the like which are provided at the lower portion of the chamber from the chamber, it is required to lift those components upward. Since, however, another substrate processing apparatus is provided above the chamber, it is difficult to lift the components such as the stage and the like up to a height position enough to allow separation thereof. When an operator inserts a hand into the lower portion of the chamber and performs cleaning, the operation cannot be effectively performed due to the presence of another substrate processing apparatus provided above the chamber.

Therefore, a plurality of substrate processing apparatuses arranged in a vertical direction needs to be spaced apart from each other by a distance that is enough to allow the maintenance operation for the lower portion of the chamber. When a large number of substrate processing apparatuses are arranged at multiple levels in a vertical direction while being spaced from each other, the entire height of the apparatuses is increased. Accordingly, the efficiency of the maintenance operation for the substrate processing apparatuses located at high level deteriorates. For that reason, it is not possible to excessively increase the number of substrate processing apparatuses arranged at multiple levels and also not possible to excessively increase the number of substrate processing apparatuses per unit area.

### SUMMARY OF THE INVENTION

In accordance with an aspect of the present invention, there is provided a substrate processing system including: a transfer unit configured to transfer a target substrate; and a plurality of substrate processing apparatuses arranged in a vertical direction along a side surface of the transfer unit and configured to process the target substrate, wherein each of the substrate processing apparatuses includes: a chamber having therein a space; a shower head provided at an upper portion of the chamber; and a stage provided at a lower portion of the chamber, wherein the chamber includes:

a first chamber component which includes a part of a sidewall defining the space in the chamber and is provided with the shower head; and a second chamber component which includes a remaining portion of the sidewall in the chamber and is provided with the stage, wherein the first chamber component and the second chamber component are separable in a direction different from an arrangement direction of the substrate processing apparatuses.

### EFFECT OF THE INVENTION

With various aspects and embodiments of the present invention, even when a plurality of substrate processing apparatuses is densely arranged in a vertical direction, the substrate processing system and the substrate processing apparatus can effectively perform the maintenance operation for each substrate processing apparatus.

### BRIEF DESCRIPTION OF THE DRAWINGS

FIG. 1 shows an exemplary substrate processing system according to an embodiment.

FIG. 2 shows an exemplary PM (Processing Module).

FIG. 3 shows exemplary processing units arranged at multiple levels.

FIG. 4 is a cross sectional view showing an exemplary processing unit.

FIG. 5 is a cross sectional view showing an exemplary processing unit.

FIG. 6 shows an exemplary processing unit in the case where an upper unit and a lower unit are separated.

FIG. 7 is a perspective view showing an example of the lower unit.

FIG. 8 is a perspective view showing an example of the upper unit.

FIGS. 9 to 12 explain a process of attaching the upper unit to the lower unit.

FIG. 13 shows another example of the upper unit and the lower unit.

FIG. 14 shows still another example of the upper unit and the lower unit.

FIG. 15 shows still another example of the lower unit.

FIG. 16 shows an exemplary high frequency power supply method.

### DETAILED DESCRIPTION OF THE EMBODIMENTS

In an embodiment of a disclosed substrate processing system, the substrate processing system includes a transfer unit configured to transfer a target substrate, and a plurality of substrate processing apparatuses arranged in a vertical direction along a side surface of the transfer unit and configured to process the target substrate. Each of the substrate processing apparatuses includes a chamber having therein a space, a shower head provided at an upper portion of the chamber, and a stage provided at a lower portion of the chamber. The chamber includes a first chamber component which includes a part of a sidewall defining the space in the chamber and is provided with the shower head and a second chamber component which includes a remaining portion of the sidewall in the chamber and is provided with the stage. The first chamber component and the second chamber component are separable in a direction different from an arrangement direction of the substrate processing apparatuses.

The chamber may have therein a cylindrical space defined by the sidewall, and at least a part of contact surfaces of the first chamber component and the second chamber component may be included in a plane obliquely intersecting a central axis of the cylindrical space.

The second chamber component may be attached to the transfer unit, and the first chamber component may be separated from the second chamber component by moving the first chamber component in a direction away from a side of the transfer unit where the second chamber component is attached.

The second chamber component may be attached to the transfer unit. The chamber may be formed by moving the first chamber component to a position close to the second chamber component from a side of the second chamber component opposite to a side of the transfer unit where the second chamber component is attached, and then moving the first chamber component in a direction perpendicular to the plane obliquely intersecting the central axis of the cylindrical space to make contact between the contact surface of the first chamber component and the contact surface of the second chamber component.

The substrate processing system may further include a power feed coil for supplying a high frequency power to each of the substrate processing apparatuses, wherein each of the substrate processing apparatuses may further include a power receiving coil, inductively coupled to the power feed coil, to which the high frequency power from the power feed coil is supplied; and a high frequency power supply unit configured to supply the high frequency power from the power receiving coil to the shower head, wherein the power receiving coil and the high frequency power supply unit may be provided at the first chamber component.

The first chamber component may further include a first temperature sensor configured to measure a temperature of the first chamber component, and a first heating unit configured to heat the first chamber component. The second chamber component may further include a second temperature sensor configured to measure a temperature of the second chamber component, and a second heating unit configured to heat the second chamber component. The substrate processing system may further include a control device configured to control a heating amount of the first heating unit and a heating amount of the second heating unit such that a temperature difference between the first chamber component and the second chamber component becomes small based on a measured value of the first temperature sensor and a measured value of the second temperature sensor.

In an embodiment of a substrate processing apparatus for processing a target substrate, which is one of a plurality of substrate processing apparatuses to be arranged in a vertical direction along a side surface of a transfer unit for transferring a target substrate, the substrate processing apparatus includes a chamber having therein a space, a shower head provided at an upper portion of the chamber, and a stage provided at a lower portion of the chamber. The chamber includes a first chamber component which includes a part of a sidewall defining the space in the chamber and is provided with the shower head, and a second chamber component which includes a remaining portion of the sidewall in the chamber and is provided with the stage. The first chamber component and the second chamber component are separable in a direction different from an arrangement direction of the substrate processing apparatuses.

Hereinafter, embodiments of a substrate processing system and a substrate processing apparatus will be described in detail with reference to the accompanying drawings. The present invention is not limited to the embodiments. The embodiments may be appropriately combined without contradicting processing contents.

(Configuration of Substrate Processing System 10)

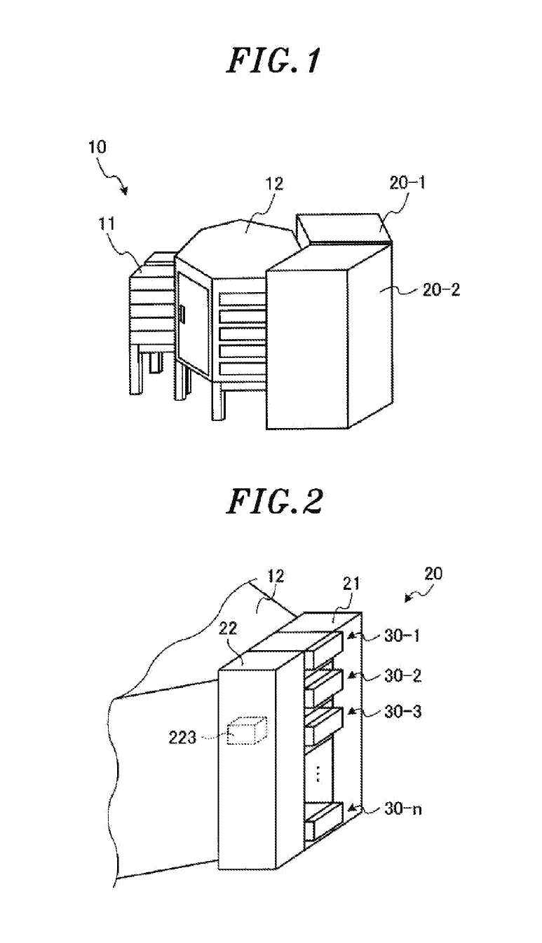

FIG. 1 shows an exemplary substrate processing system 10 according to an embodiment. FIG. 2 shows an exemplary processing module (PM) 20. As shown in FIG. 1, the substrate processing system 10 of the present embodiment includes a load-lock module (LLM) 11, a transfer module (TM) 12, and a plurality of PMs 20-1 to 20-2. In the following, the PMs 20-1 to 20-2 are collectively referred to as a PM 20 when not distinguished from one another. Although FIG. 1 shows two PMs 20, the substrate processing system 10 may include three or more PMs 20 or may include a single PM 20.

The LLM 11 is a vacuum transfer chamber of which inner space is maintained in a predetermined depressurized state so that a target substrate transferred from a loader can be transferred to a TM 12 in a depressurized state. In the TM 12, a transfer arm (not shown) is provided. The transfer arm transfers a target substrate from the LLM 11 into each of the PMs 20. The transfer arm transfers a processed substrate from each of the PMs 20 to the LLM 11.

As shown in FIG. 2, each of the PMs 20 includes a gas control unit 21, a power control unit 22, and a plurality of processing units 30-1 to 30-n. The processing units 30-1 to 30-n are arranged in a vertical direction along a side surface of the TM 12 and attached to the side surface of the TM 12. In the following, the processing units 30-1 to 30-n are collectively referred to as a processing unit 30 when not distinguished from one another.

The gas control unit 21 is connected to the respective processing units 30 via gas pipes and supplies a processing gas to the respective processing units 30 through the gas pipes. The gas control unit 21 exhausts gases in the respective processing units 30 through gas pipes.

The power control unit 22 is connected to the respective processing units 30 via power cables and communication cables. The power control unit 22 supplies power to the respective processing units 30 through the power cables. Further, the power control unit 22 includes a control device 223 for controlling temperatures of sidewalls of chambers of the respective processing units 30. The control device 223 controls the temperatures of the sidewalls of the chambers of the respective processing units 30 through the power cables.

The respective processing units 30 activate the processing gas supplied from, e.g., the gas control unit 21, by using a plasma generated by power supplied from the power control unit 22 and perform predetermined processing such as etching, film formation or the like on a target substrate by using particles of the activated processing gas.

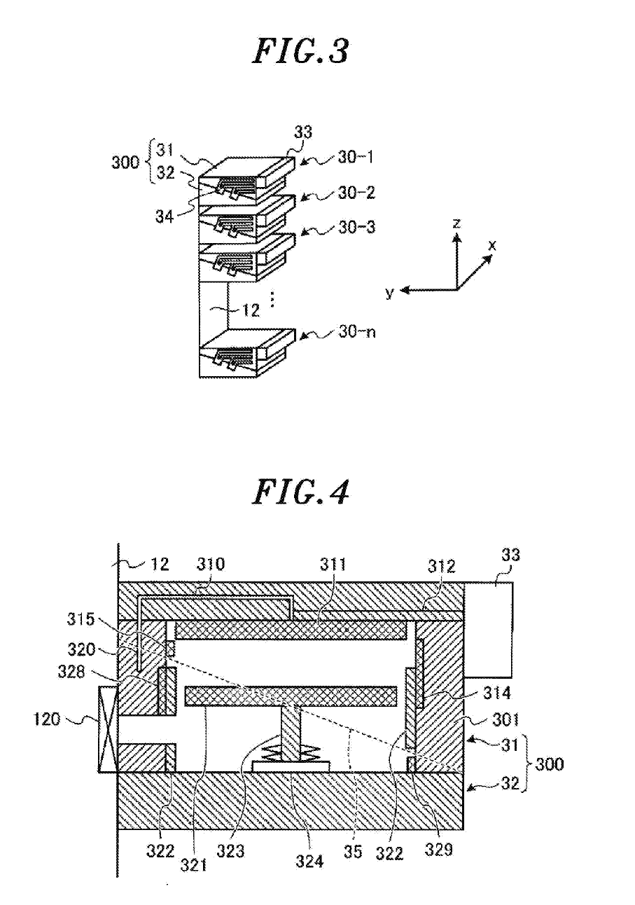

FIG. 3 shows exemplary processing units 30 arranged at multiple levels. As shown in FIG. 3, the processing units 30-1 to 30-n are arranged at multiple levels in a vertical direction (e.g., Z-axis direction in FIG. 3) along the side surface of the TM 12. Therefore, the number of processing units 30 per unit area can be increased compared to the case where a plurality of processing units 30-1 to 30-n is arranged in a horizontal direction (e.g., xy plane in FIG. 3).

As shown in FIG. 3, each of the processing units 30 includes a chamber 300, a high frequency unit 33, and a guide member 34. The chamber 300 is made of a conductive material, e.g., aluminum or the like. The chamber 300 has an upper unit 31 and a lower unit 32. When the processing unit 30 is attached to the TM 12, the upper unit 31 and the lower unit 32 are separable in a direction different from the arrangement direction of the processing units 30-1 to 30-n.

In the present embodiment, when the processing unit 30 is attached to the TM 12, it is possible to separate the upper unit 31 from the lower unit 32 by moving the upper unit 31 in a direction away from the TM 12 (e.g., in the negative Y direction in FIG. 3). The high frequency unit 33 generates a high frequency power having a predetermined frequency by using the power supplied from the power control unit 22 through the power cable. The high frequency unit 33 supplies the high frequency power thus generated to the upper unit 31.

(Configuration of Processing Unit 30)

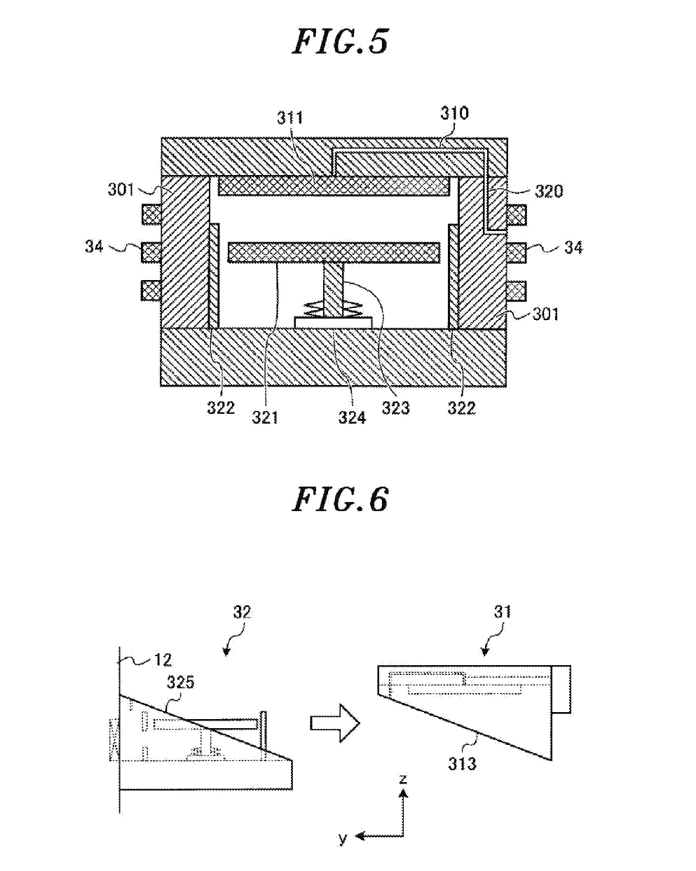

FIGS. 4 and 5 are cross sectional views showing an exemplary processing unit 30. FIG. 4 illustrates a cross section obtained by cutting a substantially central portion of the processing unit 30 along the yz plane in FIG. 3 which is seen from the x direction. FIG. 5 illustrates a cross section obtained by cutting the substantially central portion of the processing unit 30 along the xz plane in FIG. 3 which is seen from the y direction. In FIG. 4, for easy understanding, a boundary between the upper unit 31 and the lower unit 32 is indicated by a dashed line 35.

The processing unit 30 includes a sidewall 301 forming a cylindrical space (hereinafter, referred to as “processing space”) inside the chamber 300. The upper unit 31 includes a part of the sidewall 301 and the lower unit 32 includes the remaining part of the sidewall 301. In the present embodiment, the part of the sidewall 301 which is included in the upper unit 31 indicates, e.g., a part of the sidewall 301 which is positioned above a dashed line 35. Further, in the present embodiment, the remaining part of the sidewall 301 which is included in the lower unit 32 indicates, e.g., a part of the sidewall 301 which is positioned below the dashed line 35.

A chamber 300 is formed by contact between a bottom surface (hereinafter, referred to as “contact surface 313”) of the upper unit 31 and a top surface (hereinafter, referred to as “contact surface 325”) of the lower unit 32. In the present embodiment, the contact surfaces 313 and 325 are included in a plane obliquely intersecting a central axis of the cylindrical processing space defined by the sidewall 301. This plane is downwardly inclined in a direction away from the TM 12 in a state where the processing unit 30 is attached to the TM 12.

As shown in FIGS. 4 and 5, the lower unit 32 includes a gas supply line 320, a stage 321, a deposition shield 322, an elevation shaft 323, a driving unit 324, a heating unit 328, and a temperature sensor 329. The stage 321 is made of, e.g., aluminum or the like, and supports a target substrate in a substantially horizontal position. The stage 321 serves as a lower electrode with respect to a shower head 311 to be described later. The elevation shaft 323 supports the stage 321 and can vertically move the stage 321 by using the driving unit 324 such as a ball screw mechanism or the like.

The deposition shield 322 for preventing an etching by-product (deposit) from being adhered to the sidewall 301 is provided at an inner surface of the sidewall 301 to surround the stage 321. Formed at a side surface of the TM 12 are an opening for loading a target substrate into the processing unit 30 or unloading a processed substrate from the processing unit 30 and a gate valve 120 for opening/closing the opening. An opening is formed at the sidewall 301 and the deposition shield 322 so as to correspond to the gate valve 120. A ground electrode may be provided in the deposition shield 322. Accordingly, RF ground uniformity of the upper unit 31 and the lower unit 32 can be improved. The ground electrode may be provided with an impedance control unit.

The gas supply line 320 supplies a processing gas from the gas control unit 21 to the upper unit 31. The lower unit 32 is provided with a gas exhaust unit for decreasing a pressure in the chamber 300 to a predetermined level by exhausting a gas in the chamber 300 by using the gas control unit 21.

The temperature sensor 329 is provided at the sidewall 301 of the lower unit 32 and measures a temperature of the sidewall 301. The temperature sensor 329 transmits a signal indicating the measured temperature to the control device 223 in the power control unit 22 through a communication cable. The heating unit 328 is provided at the sidewall 301 of the lower unit 32. The heating unit 328 receives the control signal from the control device 223 through a communication cable and heats the sidewall 301 of the lower unit 32 in accordance with the received control signal.

As shown in FIGS. 4 and 5, the upper unit 31 includes a gas supply line 310, a shower head 311, a cable 312, a heating unit 314, and a temperature sensor 315. When the chamber 300 is formed by the contact between the upper unit 31 and the lower unit 32, the shower head 311 is provided above the stage 321 to face the stage 321.

The gas supply line 310 supplies a processing gas from the gas supply line 320 of the lower unit 32 to the shower head 311. A plurality of gas supply holes for injecting the processing gas into the processing space in the chamber 300 is formed at a bottom surface of the shower head 311. The processing gas supplied through the gas supply line 310 is injected from the gas supply holes of the shower head 311 into the processing space in the chamber 300.

A high frequency power from the high frequency unit 33 is supplied through the cable 312 to the shower head 311. The shower head 311 radiates the high frequency power supplied through the cable 312 into the processing space in the chamber 300. The shower head 311 serves as the upper electrode, while the stage 321 serves as the lower electrode.

In the present embodiment, the gate valve 120 is opened and the target substrate is loaded into the chamber 300 and mounted on the stage 321. Then, the pressure in the chamber 300 is decreased to a predetermined level by the gas exhaust unit in the lower unit 32. Then, the processing gas is supplied into the processing space in the chamber 300 through the shower head 311, and the high frequency power is radiated to the processing space in the chamber 30 from the high frequency unit 33 through the chamber 30. Accordingly, a plasma of the processing gas is generated in the processing space in the shower head 311, and predetermined processing such as etching or the like is performed on the target substrate on the stage 321 by the generated plasma.

The temperature sensor 315 is provided at the sidewall 301 of the upper unit 31 and measures a temperature of the sidewall 301 of the upper unit 31. The temperature sensor 315 transmits a signal indicating the measured temperature to the control device 223 in the power control unit 22 through the communication cable. The heating unit 314 is provided at the sidewall 301 of the upper unit 31. The heating unit 314 receives the control signal from the control device 223 through the communication cable and heats the sidewall 301 of the upper unit 31 in accordance with the received control signal.

The control device 223 in the power control unit 22 receives a signal indicating a temperature from the temperature sensor 315 in the upper unit 31 and a signal indicating a temperature from the temperature sensor 329 in the lower unit 32 through the communication cables. Further, in order to reduce a temperature difference between the sidewall 301 of the upper unit 31 and the sidewall 301 of the lower unit 32, the control device 223 calculates the heating amount of the heating unit 314 in the upper unit 31 and the heating amount of the heating unit 328 in the lower unit 32 based on the temperatures indicated by the received signals. Moreover, the control device 223 transmits control signals indicating the calculated heating amount to the heating unit 314 in the upper unit 31 and the heating unit 328 in the lower unit 32 through the communication cables.

When the substrate is processed, the chamber 300 may be locally heated by heat generated by the plasma or the like. Accordingly, when the temperature difference between the upper unit 31 and the lower unit 32 is increased, the contact portion between the upper unit 31 and the lower unit is deformed by dimensional changes due to thermal expansion, which may cause adverse effect to the processing. On the other hand, in the present embodiment, the control device 223 controls the heating amount of the heating unit 314 in the upper unit 31 and the heating amount of the heating unit 328 in the lower unit 32 such that the temperature difference between the sidewall 301 of the upper unit 31 and the sidewall 301 of the lower unit 32 becomes small. Accordingly, the control device 223 can improve the uniformity of the temperature distribution in the chamber 300.

In addition, a member made of a material having high thermal conductivity may be provided between the contact surface 313 of the upper unit 31 and the contact surface 325 of the lower unit 32. Accordingly, the temperature difference between the sidewall 301 of the upper unit 31 and the sidewall 301 of the lower unit 32 can be further reduced. The member provided between the contact surface 313 of the upper unit 31 and the contact surface 325 of the lower unit is preferably made of a material having high electric conductivity. Accordingly, a potential difference between the sidewall 301 of the upper unit 31 and the sidewall 301 of the lower unit 32 can be reduced.

FIG. 6 shows an exemplary processing unit 30 in the case where the upper unit 31 and the lower unit 32 are separated. The upper unit 31 and the lower unit 32 are separated by the plane obliquely intersecting the central axis of the cylindrical processing space defined by the sidewall 301. This plane is inclined downwardly in a direction away from the TM 12 in a state where the processing unit 30 is attached to the TM 12.

Therefore, when the upper unit 31 and the lower unit 32 are separated as shown in FIG. 6, the processing space in the chamber 300 is obliquely opened along the contact surface 325 of the lower unit 32. Accordingly, it is easy for an operator to insert a hand into the lower unit 32 or take out a component in the lower unit 32 along a direction (e.g., Y-axis direction in FIG. 6) different from the direction (e.g., Z-axis direction in FIG. 6) in which the processing units 30-1 to 30-n area arranged.

Further, the operator can perform the maintenance operation for the lower unit 32 without providing a space for the maintenance operation for the processing unit 30 in the arrangement direction of the processing units 30-1 to 30-n. Accordingly, the processing units 30-1 to 30-n can be densely arranged in a vertical direction, and the number of the processing units 30 per unit area can be increased.

By separating the upper unit 31 from the lower unit 32 and then moving the upper unit 31 to a location where a sufficient operation space is ensured, the operator can easily clean the upper unit 31 or separate the components from the upper unit 31.

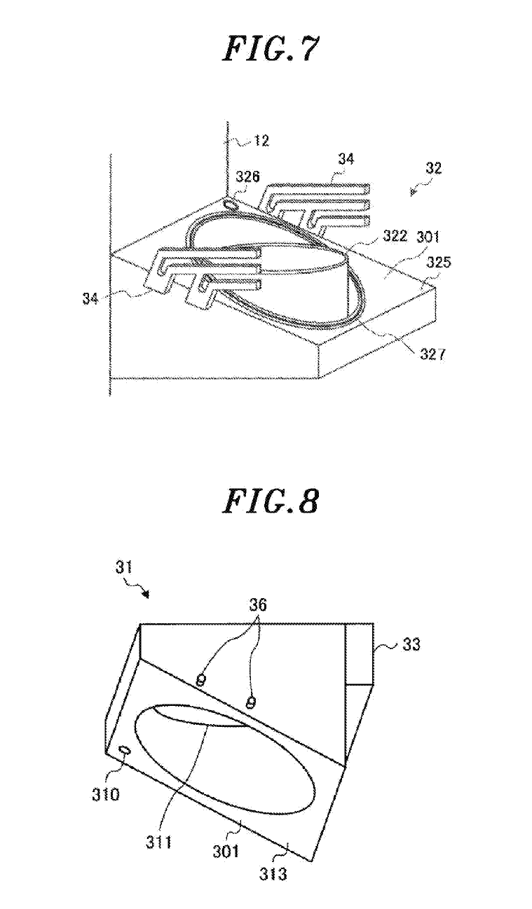

FIG. 7 is a perspective view showing an exemplary lower unit 32. FIG. 8 is a perspective view showing an exemplary upper unit 31. As shown in FIG. 7, on the contact surface 325 of the lower unit 32, an O-ring 327 is provided along the contact surface 325 to surround the processing space. Accordingly, when the chamber 300 is formed by the contact between the contact surface 313 of the upper unit 31 and the contact surface 325 of the lower unit 32, the O-ring 327 on the contact surface 325 is pressed by the contact surface 313 of the upper unit 31. As a consequence, the processing space in the chamber 300 formed by the contact between the upper unit 31 and the lower unit 32 can be airtightly maintained.

On the contact surface 325 of the lower unit 32, an O-ring 326 is provided along the contact surface 325 to surround an opening end of the gas supply line 320. Therefore, when the chamber 300 is formed by the contact between the contact surface 313 of the upper unit 31 and the contact surface 325 of the lower unit 32, the O-ring 326 on the contact surface 325 is pressed by the contact surface 313 of the upper unit 31. Accordingly, the gas supply line 320 of the lower unit 32 and the gas supply line 310 of the upper unit 31 can be airtightly connected to each other.

The O-rings 326 and 327 are provided along the contact surface 325 formed in a planar shape. Therefore, the O-rings 326 and 327 can be formed in a planar shape. Accordingly, a manufacturing cost of a seal member can be reduced compared to the case of using a three-dimensional seal member formed along contact surfaces formed of a plurality of different planes.

As shown in FIG. 7, guide members 34 are provided at side surfaces of the lower unit 32. In the present embodiment, each of the guide members 34 has two rails. As shown in FIG. 8, a plurality of protrusions 36 for moving the upper unit 31 along the rails of the guide members 34 provided at the lower unit 32 is formed at the side surfaces of the upper unit 31. In the present embodiment, two protrusions 36 are formed at each side surface of the upper unit 31.

(Attachment Method of Processing Unit 30)

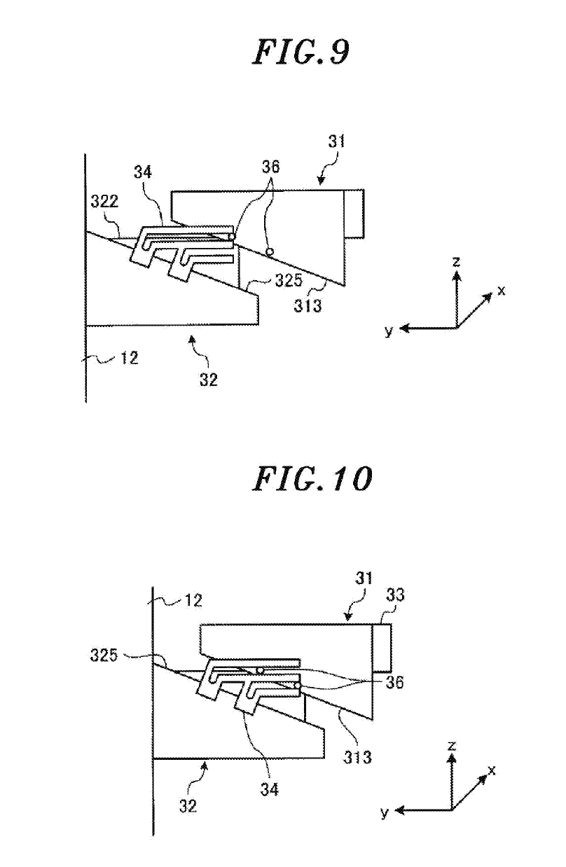

FIGS. 9 to 12 explain a process of attaching the upper unit 31 to the lower unit 32. In the examples shown in FIGS. 9 to 12, the lower unit 32 is attached to the TM 12. First, the operator makes the upper unit 31 close to the lower unit 32 by moving the upper unit 31 in a direction toward the TM 12 (e.g., Y-direction in FIG. 9). Then, as shown in FIG. 9, the operator allows upper protrusions 36 formed at the side surfaces of the upper unit 31 to be positioned on upper rails of the guide members 34.

Next, the operator further moves the upper unit 31 toward the TM 12 while moving the upper protrusions 36 along the upper rails of the guide member 34. Then, as shown in FIG. 10, the operator allows lower protrusions 36 formed at the side surfaces of the upper unit 31 to be positioned on lower rails of the guide members 34. Thereafter, the operator further moves the upper unit 31 toward the TM 12 while moving the protrusions 36 along the rails of the guide member 34. Accordingly, the operator can move the upper unit 31 to a predetermined position toward the TM 12 without contact between the contact surface 313 of the upper unit 31 and the O-rings 326 and 327 provided on the contact surface 325 of the lower unit 32.

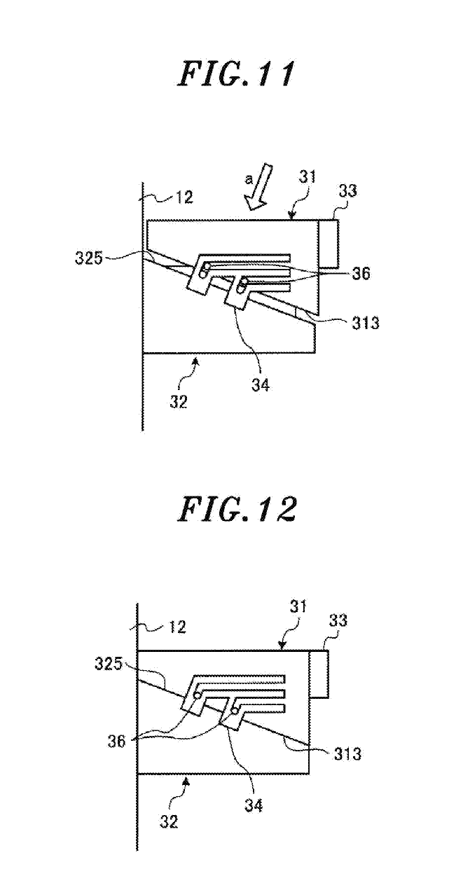

After the upper unit 31 is moved to, e.g., a position shown in FIG. 11, the operator moves the upper unit 31 in a direction (e.g., direction “a” in FIG. 11) perpendicular to the contact surface 325 of the lower unit 32 so that the protrusions 36 can be moved along the rails of the guide member 34. Accordingly, as shown in FIG. 12, the upper unit 31 and the lower unit 32 are brought into contact with each other, thereby forming the chamber 300. In order to separate the upper unit 31 and the lower unit 32, the operations illustrated in FIGS. 9 to 11 may be performed in a reverse order.

In the present embodiment, after the upper unit 31 is moved to the position shown in FIG. 11 in the direction toward the TM 12, the upper unit 31 is moved in a direction perpendicular to the contact surface 325 along the rails of the guide members 34. As a consequence, the upper unit 31 and the lower unit 32 are brought into contact with each other.

Therefore, the O-rings 326 and 327 provided on the contact surface 325 of the lower unit 32 are pressed by the contact surface 313 of the upper unit 31 in a direction perpendicular to the contact surface 325. Accordingly, deviation or twist of the O-rings 326 and 327 can be prevented. As a result, the processing space in the chamber 300 formed by the contact between the upper unit 31 and the lower unit 32 can be airtightly maintained. Further, the decrease in airtightness of the gas supply line 320 of the lower unit 32 and the gas supply line 310 of the upper unit 31 can be prevented.

When the evacuation of the chamber 300 is started, the upper unit 31 and the lower unit 32 are brought into close contact with each other by the decrease in the pressure in the chamber 300. Before the start of the evacuation of the chamber 300, the pressure in the chamber 300 is equal to an external pressure. Since the contact surface 325 of the lower unit 32 is inclined, the upper unit 31 needs to be prevented from slipping down from the lower unit 32 until the evacuation of the chamber 300 is started.

However, in the present embodiment, the guide members 34 restrict the movement of the upper unit 31 even after the upper unit 31 and the lower unit 32 are brought into contact with each other. Therefore, the upper unit 31 does not slip down from the lower unit 32 without providing an additional mechanism for preventing the upper unit 31 from slipping down from the lower unit 32.

In the substrate processing system 10 according to the above-described embodiment, even when the processing units are densely arranged in a vertical direction, the maintenance operation for the processing units 30 can be efficiency performed.

The present invention is not limited to the above-described embodiment and may be variously modified within the scope not departing from the gist of the present invention.

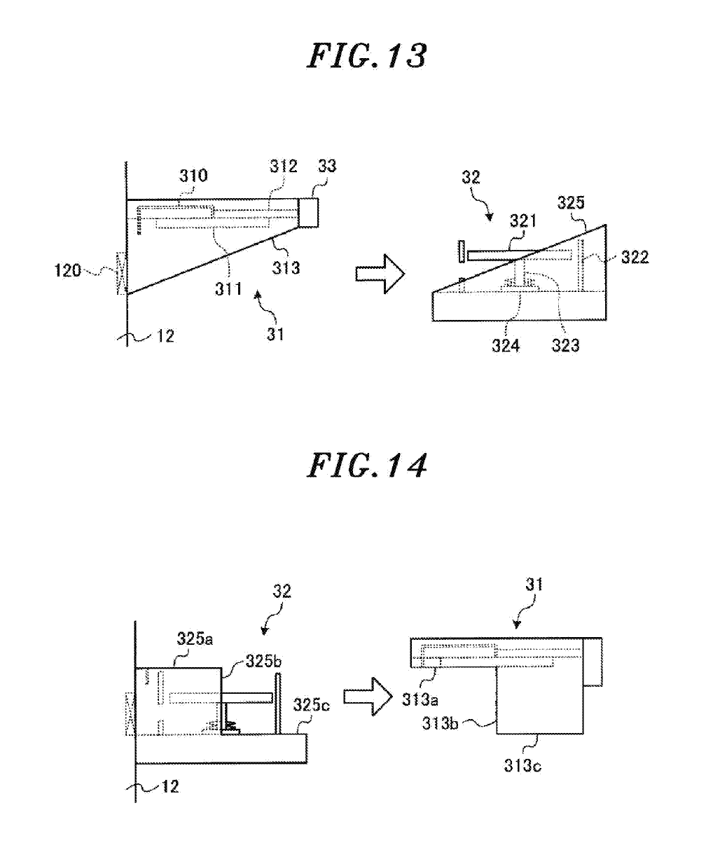

For example, in the above-described embodiment, the upper unit 31 is separated from the lower unit 32 attached to the TM 12. However, the present invention is not limited thereto. For example, as shown in FIG. 13, the lower unit 32 may be separated from the upper unit 31 attached to the TM 12. In that case, the plane including the contact surface between the upper unit 31 and the lower unit 32 may be inclined upward as it goes away from the TM 12, in a state where the processing unit 30 is attached to the TM 12.

In the example shown in FIG. 13, the contact surface 325 of the lower unit 32 can be made to be in contact with the contact surface 313 of the upper unit 31 in a direction perpendicular to the contact surface 313 by providing guide members 34 having an upside-down shape of the guide members 34 shown in FIG. 7 at the side surfaces of the upper unit 31 and providing protrusions 36 corresponding to the guide members 34 at the side surfaces of the lower unit 32.

In the example shown in FIG. 13, when the processing unit 30 is formed, there is required a mechanism for maintaining the contact state between the lower unit 32 and the upper unit 31 so that the lower unit 32 does not fall down from the upper unit 31 until a pressure in the chamber 300 becomes a negative pressure after the upper unit 31 and the lower unit 32 are brought into contact with each other. As for the mechanism for maintaining the contact state between the lower unit 32 and the upper unit 31, there is considered a mechanism for biasing the lower unit 32 in a direction perpendicular to the contact surface 313 of the upper unit 31 by using, e.g., a spring, rubber, a cylinder or the like.

In the above-described embodiment, the contact surface between the upper unit 31 and the lower unit 32 is included in a single plane. However, the present invention is not limited thereto. For example, as shown in FIG. 14, the upper unit 31 and the lower unit 32 may be in contact with each other on a plurality of planes including contact surfaces between the upper unit 31 and the lower unit 32. In the example shown in FIG. 14, contact surfaces 325a, 325b and 325c of the lower unit 32 are included in different planes, and contact surfaces 313a, 313b and 313c of the upper unit 31 are included in different planes.

However, in the example shown in FIG. 14, a contact surface on which a single O-ring is provided is preferably a single plane. When a plurality of O-rings is provided, surfaces on which the respective O-rings are provided are preferably in parallel with one another. Accordingly, the upper unit 31 and the lower unit 32 can be brought into contact with each other by moving the upper unit 31 in a direction perpendicular to the surface on which the O-ring is provided. As a result, deviation or twist of the O-ring can be prevented.

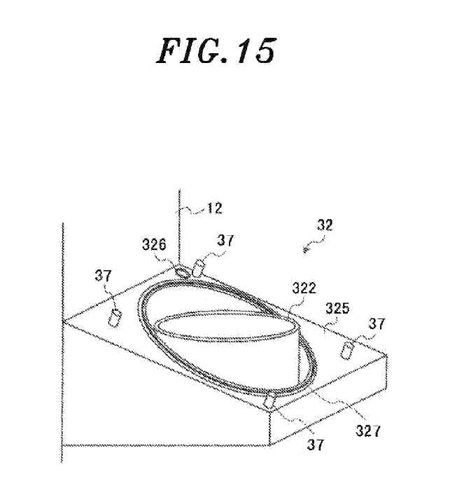

In the above-described embodiment, the upper unit 31 and the lower unit 32 are brought into contact with each other by moving the upper unit 31 in a direction perpendicular to the contact surface 325 of the lower unit on which the O-ring is provided by using the guide members 34 and the protrusions 36. However, the present invention is not limited thereto. For example, as shown in FIG. 15, a plurality of guide pins 37 extending in a direction perpendicular to the contact surface 325 may be provided on the contact surface 325 on which the O-ring is provided.

In that case, insertion holes are formed at the contact surface 313 of the upper unit 31 in a direction perpendicular to the contact surface 313. The insertion holes have a shape slightly greater than the guide pins 37. Further, the insertion holes are provided at positions corresponding to the guide pins 37. In the example shown in FIG. 15, the upper unit 31 and the lower unit 32 can be brought into contact with each other by moving the upper unit 31 in a direction perpendicular to the surface on which the O-ring is provided. Accordingly, deviation or twist of the O-ring can be prevented. The guide pins 37 restrict the movement of the upper unit 31 even after the upper unit 31 and the lower unit 32 are brought into contact with each other. Therefore, the upper unit 31 does not slip down from the lower unit 32.

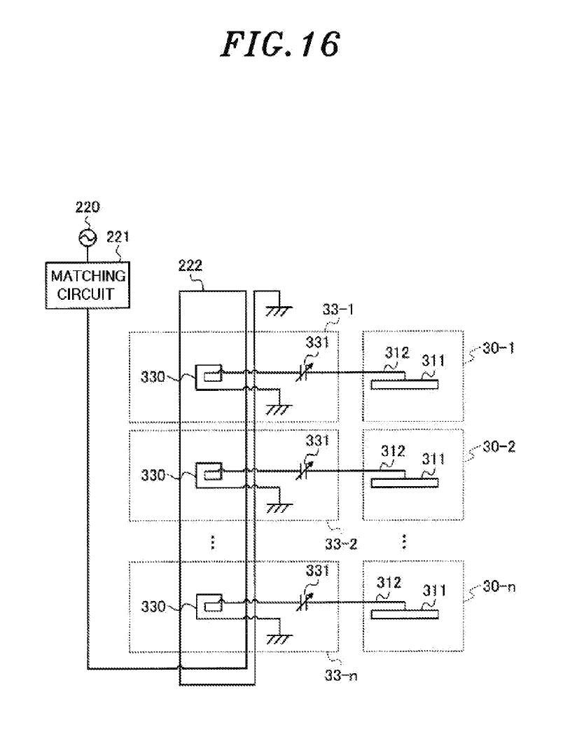

In the above embodiment, the high frequency unit 33 generates a high frequency power having a predetermined frequency by using power supplied from the power control unit 22 through a cable and supplies the generated high frequency power to the shower head 311. However, the present invention is not limited thereto. FIG. 16 shows another exemplary high frequency power supply method.

In the example shown in FIG. 16, a power supply 220, a matching circuit 221, and a loop antenna 222 are provided in the power control unit 22. The loop antenna 222 generates a high frequency power having a predetermined frequency based on power supplied from the power supply 220 through the matching circuit 221.

Each of the high frequency units 33-1 to 33-n includes a loop antenna 330 and a matching capacitor 331. The loop antenna 330 is provided, e.g., at a side surface of the processing unit 30 which faces the power control unit 22. The loop antenna 330 is inductively coupled to the loop antenna 222 and receives the high frequency power generated by the loop antenna 222 by electromagnetic field resonance. Further, the loop antenna 330 supplies the received high frequency power to the shower head 311 through the matching capacitor 331 and the cable 312. Therefore, the number of cables that connect the power control unit 22 and the respective processing units 30 can be reduced. Accordingly, the efficiency of the maintenance operation for the processing units 30 can be improved.

In the above-described embodiment, the processing unit 30 for processing a target substrate by using a plasma has been described as an example. However, the present invention is not limited thereto. For example, the present invention can also be applied to a processing module in which a plurality of substrate processing apparatuses such as a thermal CVD (Chemical Vapor Deposition) apparatus, a dry cleaning apparatus or the like is arranged at multiple levels in a vertical direction.

While the invention has been shown and described with respect to the embodiments, it will be understood by those skilled in the art that various changes and modifications may be made without departing from the scope of the invention as defined in the following claims.

### DESCRIPTION OF REFERENCE NUMERALS

10: substrate processing system

12: TM

30: processing unit

300: chamber

301: sidewall

31: upper unit

311: shower head

32: lower unit

321: stage

What is claimed is:

1. A substrate processing system comprising:
a transfer unit configured to transfer a target substrate; and
a plurality of substrate processing apparatuses arranged in a vertical direction along a side surface of the transfer unit and configured to process the target substrate,
wherein each of the substrate processing apparatuses includes:
a chamber having therein a space;
a shower head provided at an upper portion of the chamber; and
a stage provided at a lower portion of the chamber,
wherein the chamber includes:
a first chamber component which includes a part of a sidewall defining the space in the chamber and is provided with the shower head; and
a second chamber component which includes a remaining portion of the sidewall in the chamber and is provided with the stage,
wherein the first chamber component and the second chamber component are separable in a direction different from an arrangement direction of the substrate processing apparatuses.

2. The substrate processing system of claim 1, wherein the chamber has therein a cylindrical space defined by the sidewall, and
at least a part of contact surfaces of the first chamber component and the second chamber component is included in a plane obliquely intersecting a central axis of the cylindrical space.

3. The substrate processing system of claim 2, wherein the second chamber component is attached to the transfer unit, and
the first chamber component is separated from the second chamber component by moving the first chamber component in a direction away from a side of the transfer unit where the second chamber component is attached.

4. The substrate processing system of claim 2, wherein the chamber is formed by moving the first chamber component to a position close to the second chamber component from a side of the second chamber component opposite to a side of the transfer unit where the second chamber component is attached, and then moving the first chamber component in a direction perpendicular to the plane obliquely intersecting the central axis of the cylindrical space to make contact between the contact surface of the first chamber component and the contact surface of the second chamber component.

5. The substrate processing system of claim 1, further comprising a power feed coil for supplying a high frequency power to each of the substrate processing apparatuses,
wherein each of the substrate processing apparatuses further includes:
a power receiving coil, inductively coupled to the power feed coil, to which the high frequency power from the power feed coil is supplied; and
a high frequency power supply unit configured to supply the high frequency power from the power receiving coil to the shower head,
wherein the power receiving coil and the high frequency power supply unit are provided at the first chamber component.

6. The substrate processing system of claim 1, wherein the first chamber component further includes:
a first temperature sensor configured to measure a temperature of the first chamber component; and
a first heating unit configured to heat the first chamber component,
wherein the second chamber component further includes:
a second temperature sensor configured to measure a temperature of the second chamber component; and
a second heating unit configured to heat the second chamber component, and
wherein the substrate processing system further comprises:
a control device configured to control a heating amount of the first heating unit and a heating amount of the second heating unit such that a temperature difference between the first chamber component and the second chamber component becomes small based on a measured value of the first temperature sensor and a measured value of the second temperature sensor.

7. A substrate processing apparatus for processing a target substrate, which is one of a plurality of substrate processing apparatuses to be arranged in a vertical direction along a side surface of a transfer unit for transferring a target substrate, the substrate processing apparatus comprising:
a chamber having therein a space;
a shower head provided at an upper portion of the chamber; and
a stage provided at a lower portion of the chamber,
wherein the chamber includes:
a first chamber component which includes a part of a sidewall defining the space in the chamber and is provided with the shower head; and
a second chamber component which includes a remaining portion of the sidewall in the chamber and is provided with the stage,
wherein the first chamber component and the second chamber component are separable in a direction different from an arrangement direction of the substrate processing apparatuses.
